(19) United States
(12) Patent Application Publication
(10) Pub. No.: US 2017/0121842 A1
(43) Pub. Date: May 4, 2017

(54) APPARATUS FOR ELECTROCHEMICAL ETCHING AND APPARATUS FOR ELECTROPLATING

(71) Applicant: Industrial Technology Research Institute, Hsinchu (TW)

(72) Inventor: Teng-Yu Wang, Taipei City (TW)

(21) Appl. No.: 14/977,660

(22) Filed: Dec. 22, 2015

(30) Foreign Application Priority Data
Nov. 3, 2015 (TW) 104136119

(51) Int. Cl. C25F 3/12; C25F 3/14; C25D 17/00; C25D 5/02; C25D 5/08; H01L 31/18; C25F 7/00

(52) U.S. Cl. CPC C25F 3/12; H01L 31/1876; C25F 3/14; C25F 7/00; C25D 5/026; C25D 5/08; C25D 17/001

(57) ABSTRACT

An apparatus for electrochemical etching and an apparatus for electroplating are provided, wherein the apparatus for electrochemical etching includes an etching solution spraying head, a support, and a first and a second electrode. The first electrode is disposed inside the etching solution spraying head, and current is provided to an etching solution inside the etching solution spraying head by the first electrode. The support is disposed opposite to the etching solution spraying head. The second electrode is disposed on the support. When a substrate is placed on the second electrode, a first surface of the substrate is in electrical contact with the second electrode, and the etching solution sprayed from the etching solution spraying head can naturally flow through a second surface of the substrate and then flow off from the edges of the support.

### CROSS-REFERENCE TO RELATED APPLICATION

This application claims the priority benefit of Taiwan application no. 104136119, filed on Nov. 3, 2015. The entirety of the above-mentioned patent application is hereby incorporated by reference herein and made a part of this specification.

### TECHNICAL FIELD

The disclosure is related to an apparatus for electrochemical etching and an apparatus for electroplating.

### BACKGROUND

Electrochemical techniques are related to the interactive change effect and the conversion process of electrical energy and chemical energy, such as electroplating and electrochemical etching.

In the case of the current kerf-free wafer process for reducing manufacturing costs of the solar cell, electrochemical etching is needed to perform the step of porous silicon etching. Although an experiment of porous silicon etching is readily performed on a single wafer, the difficulty is much greater when the experiment is performed on a plurality of wafers at the same time, for three reasons. The first is that the etching solution is hydrofluoric acid, and therefore the electrode can only adopt platinum. When a traditional design is adopted, the amount of platinum electrode used is large, and since platinum is expensive, the price of the platinum usage is almost the same as the price of an apparatus, which is not practical in terms of costs. The second reason is that current needs to pass through the wafer to achieve the object of porous silicon etching, and if current is short-circuited in the solution before passing through the wafer, then etching is not performed, and therefore the etching solution needs to isolated between wafers, thus causing difficulty in the manufacture of a mass produced apparatus. The third reason is the issue of bubbles. Electrochemical etching of a silicon wafer generates a large amount of bubbles, and the bubbles cause uneven etching, and therefore the issue of bubble elimination needs to be considered in the design of the apparatus.

In recent years, many research institutes have conducted research relating to the kerf-free wafer process. However, only experimental results are seen in published literature because in most experiments, a single wafer is used for experimentation instead of using a large quantity of wafers.

### SUMMARY

An apparatus for electrochemical etching of the disclosure can perform electrochemical etching on a substrate, wherein the substrate has a first surface and a second surface. The apparatus for electrochemical etching includes an etching solution spraying head, a support, and a first and a second electrode. The first electrode is disposed in the etching solution spraying head as a negative electrode (cathode), and current is applied to an etching solution inside the etching solution spraying head by the first electrode. The support is disposed opposite to the etching solution spraying head. The second electrode is disposed on the support as a positive electrode (anode). When the substrate is disposed on the second electrode, the first surface of the substrate is in electrical contact with the second electrode, and the etching solution sprayed from the etching solution spraying head can naturally flow through the second surface of the substrate and then flow off from the edges of the support.

An apparatus for electroplating of the disclosure can perform electroplating on a substrate, wherein the substrate has a first surface and a second surface. The apparatus for electroplating includes an electroplating solution spraying head, a support, and a first and a second electrode. The first electrode is disposed inside the electroplating solution spraying head as a positive electrode (anode), wherein current is provided to an electroplating solution inside the electroplating solution spraying head by the first electrode. The support is disposed opposite to the electroplating solution spraying head. The second electrode is disposed on the support as a negative electrode (cathode). When the substrate is disposed on the second electrode, the first surface of the substrate is in electrical contact with the second electrode, and the electroplating solution sprayed from the electroplating solution spraying head can naturally flow through the second surface of the substrate and then flow off from the edges of the support.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-section of an apparatus for electrochemical etching according to the first embodiment of the disclosure.

FIG. 2 is a cross-section of another apparatus for electrochemical etching of the first embodiment.

FIG. 3A to FIG. 3C are cross-sections of three examples of a support in the apparatus for electrochemical etching of the first embodiment.

FIG. 4 is a cross-section of an apparatus for electroplating according to the second embodiment of the disclosure.

FIG. 5 is a cross-section of another apparatus for electroplating of the second embodiment.

FIG. 6A and FIG. 6B are three-dimensional schematics of two different multi-piece processing apparatuses according to the third embodiment of the disclosure.

### DETAILED DESCRIPTION OF DISCLOSED EMBODIMENTS

Herein, embodiments of the disclosure concept are more specifically described with reference to figures, but the disclosure can still be implemented in many different forms. In the figures, for clarity, the relative size and the location of each structure and region may be reduced or enlarged. It should further be understood that, although terms such as “first” and “second” . . . etc. are used to describe different structures or regions in the specification, the structures or regions should not be limited to these terms. In other words, the first surface, region, or structure discussed in the following can be referred to as the second surface, region, or structure, without departing from the teaching of the embodiments.

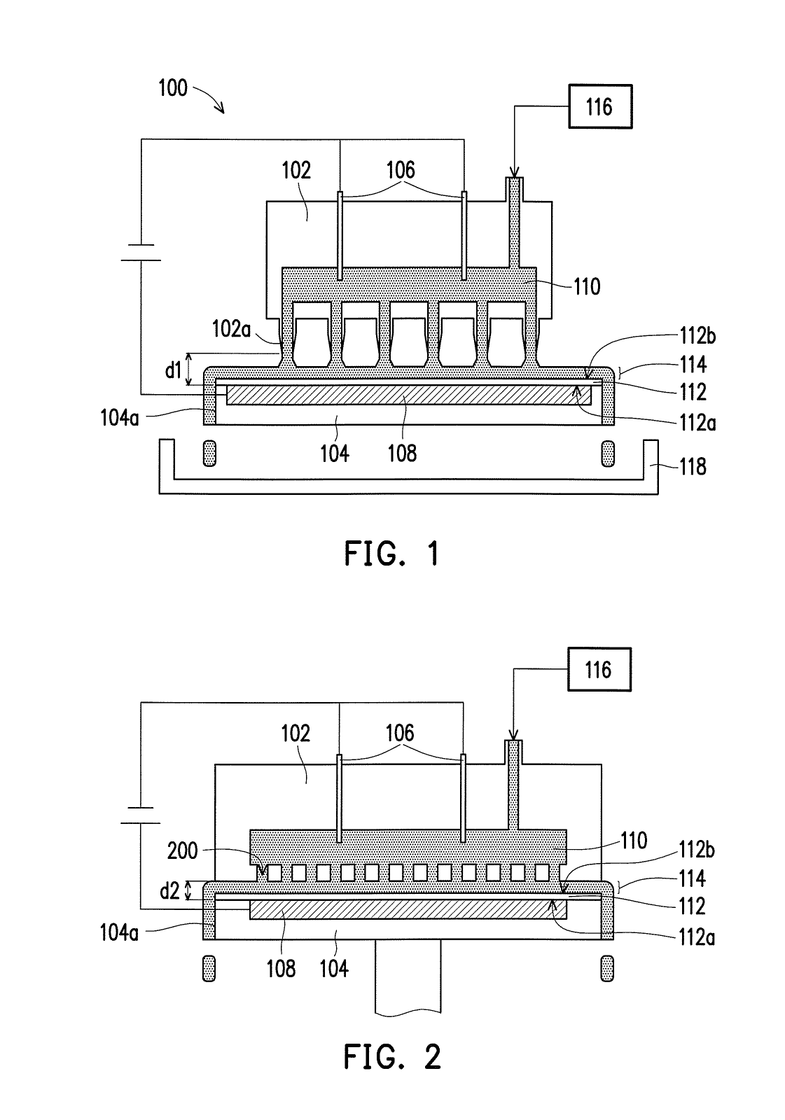

FIG. 1 is a cross-section of an apparatus for electrochemical etching according to the first embodiment of the disclosure.

Referring first to FIG. 1, an apparatus 100 for electrochemical etching of the first embodiment at least includes an etching solution spraying head 102, a support 104, a first electrode 106, and a second electrode 108. The first electrode 106 is disposed inside the etching solution spraying head 102 as a negative electrode (cathode), and current is provided to an etching solution 110 inside the etching solution spraying head 102 by the first electrode 106, wherein the first electrode 106 is, for instance, an electrode rod, and the quantity thereof can be adjusted as needed. The support 104 is disposed opposite to the etching solution spraying head 102, such as top and bottom opposites as shown in the present figure, but can also be disposed as left and right opposites as needed. The second electrode 108 is disposed on the support 104 as a positive electrode (anode); and the second electrode 108 is preferably disposed in the center of the support 104. When a substrate 112 to be etched is disposed on the second electrode 108, a first surface 112a of the substrate 112 is in electrical contact with the second electrode 108, the area of the substrate 112 is preferably greater than the area of the second electrode 108, and the etching solution 110 sprayed from the etching solution spraying head 102 can naturally flow through a second surface 112b of the substrate 112 and flow off from edges 104a of the support 104, and is not in contact with the second electrode 108, and therefore the present embodiment can readily achieve single-side etching. Moreover, since the etching solution 110 flows freely on the substrate 112, the etching solution does not readily permeate through to corrode the second electrode 108 due to pressure as in traditional immersion etching.

In the present embodiment, the etching solution spraying head 102 can have a plurality of nozzles 102a, and the quantity, the density, the distribution, and the shape . . . etc. of the nozzles 102a can be changed as needed. A spacing d1 between the etching solution spraying head 102 and the second electrode 108 is, for instance, controlled such that a liquid film 114 formed by the etching solution 110 on the second surface 112b of the substrate 112 is not discontinued (i.e., continuous). However, the disclosure is not limited thereto, and the continuity of the liquid film 114 can be ensured according to, for instance, the flow velocity of the etching solution 110 or the density of the nozzles 102a. Moreover, at least one of the etching solution spraying head 102 and the support 104 can be designed as a movable device to make suitable working space when a substrate is placed on the support 104. For instance, if the support 104 is fixed, then the etching solution spraying head 102 preferably can move up and down, such that after the substrate 112 is placed on the support 104, the etching solution spraying head 102 is lowered close to the substrate 112, and then the etching solution 110 begins to circulate through the second surface 112b of the substrate 112 and current is applied to the etching solution 110 and the substrate 112 via the first and the second electrodes 106 and 108. In contrast, if the etching solution spraying head 102 is fixed, then the support 104 preferably can move up and down. The current control during etching can be a single-stage constant current or a multi-stage variable current.

Referring further to FIG. 1, the apparatus 100 for electrochemical etching of the first embodiment can further include other components such as a solution storage tank 116 or a solution holding device 118. The solution storage tank 116 is used to store the etching solution 110 and transport the etching solution 110 from the solution storage tank 116 to the etching solution spraying head 102 via a pump pressure. The solution holding device 118 is used to hold the etching solution 110 flowing off from the edges 104a of the support 104. If a pipeline (not shown) is disposed between the solution storage tank 116 and the solution holding device 118, then the etching solution 110 can be recycled.

The apparatus 100 for electrochemical etching of the first embodiment is suitable for various electrochemical etching processes. For instance, due to the high cost of power generation, how to reduce costs for the silicon crystal solar cell receiving popular attention in recent years has always been a topic for various industries. With the advancement and development in techniques, the manufacturing costs of the solar cell have been lowered to the limit, and therefore a kerf-free wafer process has currently been developed to replace the traditional cutting process, so as to prevent material waste and as a result lower wafer costs. The kerf-free wafer process mainly consists of three steps. The first is porous silicon etching, the second is EPI epitaxial growth, and the third is wafer separation. The apparatus 100 for electrochemical etching of the first embodiment can be used in the porous silicon etching step. For instance, a platinum electrode or a silver electrode is used as the first electrode 106, and a mixed aqueous solution of hydrofluoric acid and alcohol is used as the etching solution 110. Moreover, the material of the etching solution spraying head 102 can adopt an etch-resistant material such as polytetrafluoroethylene (PTFE), polyvinyl difluoride (PVDF), perfluoroalkoxy (PFA) resin, polyvinylchloride (PVC), polypropylene (PP), high-density polyethylene (HDPE), or other suitable materials. In addition, the material of the support 104 can adopt an etch-resistant material such as PTFE, PVDF, PFA resin, PVC, PP, HDPE, or other suitable materials.

FIG. 2 is a cross-section of another apparatus for electrochemical etching of the first embodiment, wherein the same reference numerals as FIG. 1 are used to represent the same or similar components.

In FIG. 2, the etching solution spraying head 102 has a plurality of spray openings 200, and the quantity, the density, and the distribution state of the spray openings 200 can all be designed according to demand. A spacing d2 between the etching solution spraying head 102 and the second electrode 108 is controlled such that the liquid film 114 formed by the etching solution 110 on the second surface 112b of the substrate 112 is continuous. However, the disclosure is not limited thereto, and the continuity of the liquid film 114 can be ensured according to, for instance, the flow velocity of the etching solution 110 or the density of the spray openings 200.

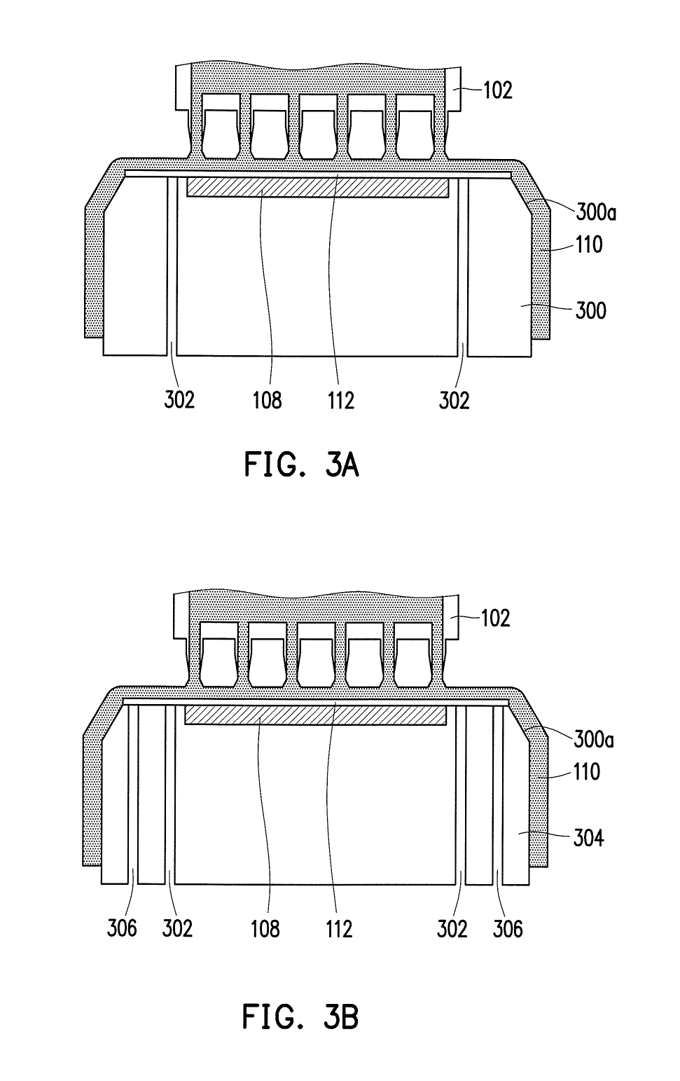

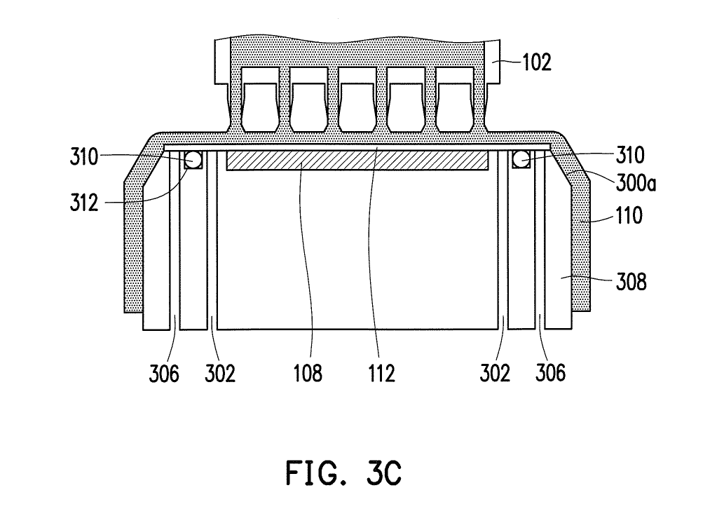

FIG. 3A to FIG. 3C are cross-sections of three examples of the support in the apparatus for electrochemical etching of the first embodiment, wherein the same reference numerals in FIG. 1 are used to represent the same or similar components, and a portion of the components in the apparatus for electrochemical etching is omitted to focus on the description of the support.

A support 300 shown in FIG. 3A includes an adsorption port 302, and the substrate 112 may be vacuum adsorbed by vacuum-pumping from the adsorption port 302. Moreover, edges 300a of the support 300 can further be designed as an arc or to have an inclination angle to facilitate discharge of the etching solution 110. The quantity and the location of the adsorption port 302 can both be changed as needed. For instance, the adsorption port 302 can be disposed in the center of the support 300 and pass through the second electrode 108, or be disposed in a region adjacent to the edges 300a outside the second electrode 108 as shown in FIG. 3A. The shape of the adsorption port 302 can be a circle, a strip, or a continuous ring surrounding the edges 300a of the support 300.

A support 304 shown in FIG. 3B has an adsorption port 302, and at least one exhaust port 306 can further be disposed in the portion closer to the edges 300a of the support 300 than the location of the adsorption port 302 to prevent the etching solution 110 from permeating through along the first surface 112a of the substrate 112 and corroding the second electrode 108. The location of the exhaust port 306 is a location corresponding to the edges of the substrate 112.

In addition to the adsorption port 302 and the exhaust port 306, a support 308 shown in FIG. 3C further has one space 312 capable of housing an O-ring 310, and the O-ring 310 surrounds the second electrode 108 and is disposed between the substrate 112 and the support 308 to prevent the etching solution 110 from being sucked by the adsorption port 302, and therefore the space 312 of the support 308 also surrounds the second electrode 108.

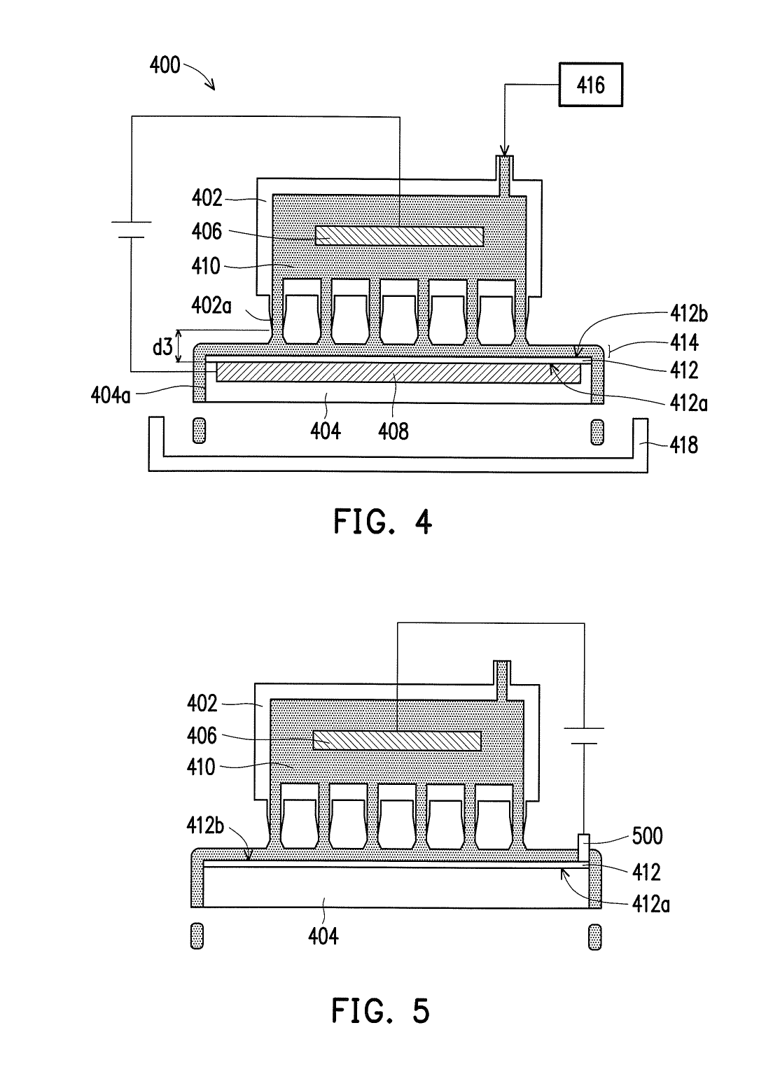

FIG. 4 is a cross-section of an apparatus for electroplating according to the second embodiment of the disclosure.

Referring to FIG. 4, an apparatus 400 for electroplating includes an electroplating solution spraying head 402, a support 404, a first electrode 406, and a second electrode 408. The first electrode 406 is disposed inside the electroplating solution spraying head 402 as a positive electrode (anode), wherein current is provided to an electroplating solution 410 inside the electroplating solution spraying head 402 by the first electrode 406, and the first electrode 406 is used as the metal ion source for electroplating at the same time. The support 404 is disposed opposite to the electroplating solution spraying head 402, such as top and bottom opposites shown in the present figure, but can also be disposed as left and right opposites as needed. The second electrode 408 is disposed on the support 404 as a negative electrode (cathode). The material of the first electrode 406 is, for instance, a metal material to be plated on a second surface 412b of the substrate 412, such as copper or nickel. When the substrate 412 is disposed on the second electrode 408, a first surface 412a of the substrate 412 is in electrical contact with the second electrode 408, and the electroplating solution 410 sprayed from the electroplating solution spraying head 402 can naturally flow through the second surface 412b of the substrate 412 and then flow off from edges 404a of the support 404, and therefore the present embodiment can readily achieve the effect of single-side electroplating. The area of the substrate 412 can be greater than the area of the second electrode 408 to ensure the electroplating solution 410 is not in contact with the second electrode 108. The substrate 412 is, for instance, a solar cell. The support 404 can further be modified with reference to FIG. 3A to FIG. 3C, and is therefore not repeated herein.

Referring further to FIG. 4, the electroplating solution spraying head 402 can have a plurality of nozzles 402a, but the disclosure is not limited thereto, and the electroplating solution spraying head can also have a plurality spray openings as shown in FIG. 2, and the nozzles 402a and the quantity, the density, the distribution state, and the shape . . . etc. of the spray openings can all be changed as needed. A spacing d3 between the electroplating solution spraying head 402 and the second electrode 408 is, for instance, controlled such that a liquid film 414 formed by the electroplating solution 410 on the second surface 412b of the substrate 412 is continuous. However, the disclosure is not limited thereto, and the continuity of the liquid film 414 can be ensured according to, for instance, the flow velocity of the electroplating solution 410 or the density of the nozzles 402a. Moreover, at least one of the electroplating solution spraying head 402 and the support 404 can be designed as a movable device, as shown in the movement relationship between the etching solution spraying head 102 and the support 104 of the first embodiment. Moreover, the apparatus 400 for electroplating of the second embodiment can further include other components, such as a solution storage tank 416 or a solution holding device 418. The solution storage tank 416 is used to store the electroplating solution 410 and transport the electroplating solution 410 from the solution storage tank 416 to the electroplating solution spraying head 402 via a pump pressure. The solution holding device 418 is used to hold the electroplating solution 410 flowing off from the edges 404a of the support 404. If a pipeline (not shown) is disposed between the solution storage tank 416 and the solution holding device 418, then the function of recycling the electroplating solution 410 can further be achieved.

In the present embodiment, by utilizing the flow and the conductive properties of the electroplating solution 410, electroplating is performed by applying current to the flowing electroplating solution 410, and as a result the metal ions of the electroplating solution 410 can be more uniform, and a protective layer is not needed on the first surface 412a of the substrate 412 (such as a solar cell), thus reducing the number of solar cell manufacture steps. This technique can be used in mass production.

FIG. 5 is a cross-section of another apparatus for electroplating of the second embodiment, wherein the same reference numerals as FIG. 4 are used to represent the same or similar components.

In FIG. 5, a second electrode 500 is directly in contact with the second surface 412b of the substrate 412. For instance, when the substrate 412 itself is a conductive material or the second surface 412b thereof has a conductive layer or a metal layer, the second electrode 500 can be in direct contact with the conductive portion, the electroplating solution 410 begins to circulate through the second surface 412b of the substrate 412, and current is applied to the electroplating solution 410 and the second electrode 500 to begin electroplating. In the present embodiment, the current control can be a single-stage constant current or a multi-stage variable current.

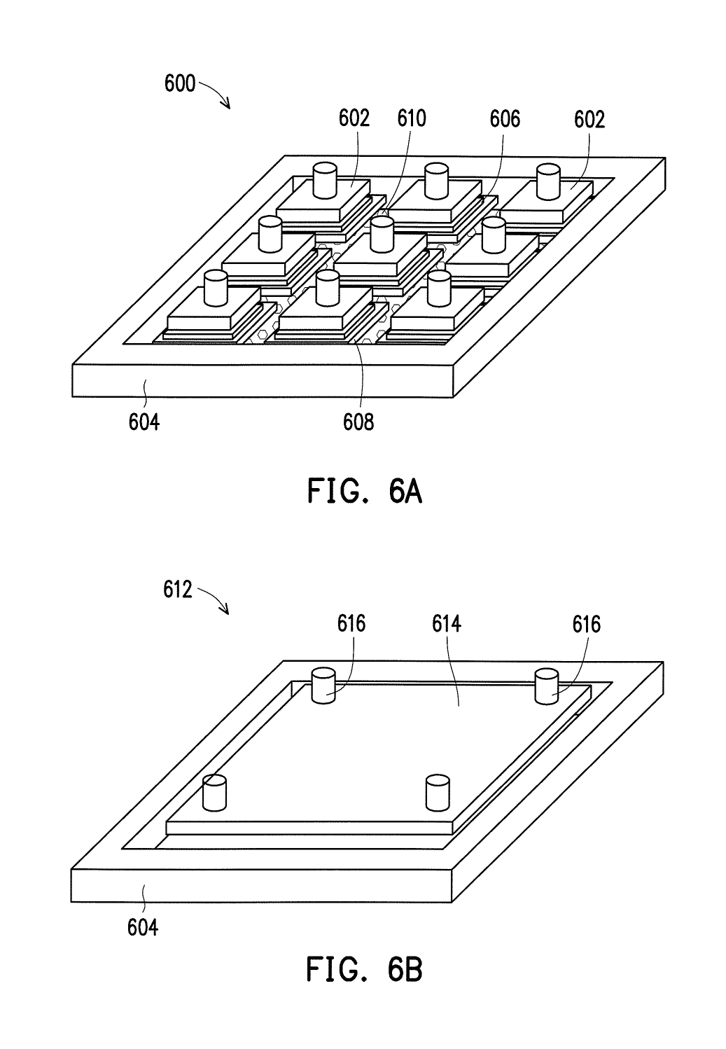

FIG. 6A and FIG. 6B are three-dimensional schematics of two different multi-piece processing apparatuses according to the third embodiment of the disclosure. The apparatus in FIG. 6A and FIG. 6B can adopt the design of the apparatus for electrochemical etching of the first embodiment or the apparatus for electroplating of the second embodiment.

An apparatus 600 of FIG. 6A has 9 etching solution (or electroplating solution) spraying heads 602 and one support 604, and therefore electrochemical etching or electroplating can be performed on 9 substrates 606 at the same time. A first electrode (not shown) is provided inside each of the etching solution spraying heads 602. The support 604 has protruding portions 608 corresponding to the 9 etching solution spraying heads 602, and a second electrode (not shown) can be disposed in each of the protruding portions 608. When electroplating or electrochemical etching is performed on a plurality of substrates, current can be provided in a series or parallel manner; and if excessive current is to be avoided during etching, then a series method is preferred. Moreover, a drainage hole 610 can further be disposed between the support 604 and the protruding portions 608 to prevent the etching solution or the electroplating solution from accumulating inside the support 604.

Although an apparatus 612 of FIG. 6B has one etching solution (or electroplating solution) spraying head 614, the etching solution (or electroplating solution) spraying head 614 can still correspond to a plurality of substrates and be provided with a plurality of electroplating solution input portions 616, and therefore with the support 604, an electrochemical etching or electroplating treatment can also be performed on a plurality of substrates to achieve the effect of mass production.

In particular, electrochemical etching is performed on a plurality of wafers at the same time, and in comparison to a traditional apparatus for porous silicon etching, the apparatuses 600 and 612 of the third embodiment can significantly reduce the amount of the platinum electrode, thus lower costs of the apparatus. Moreover, since the etching solutions flowing through each of the substrates 606 (i.e., wafers) in the apparatuses 600 and 612 are separated from one another, the occurrence of the issue in which current is short-circuited in the solution before passing through the wafer in a traditional apparatus for porous silicon etching can be avoided. Moreover, since the etching solution flows freely, the large amount of bubbles generated by porous silicon etching can be washed away by the etching solution to prevent the issue of uneven etching caused by bubbles.

Experiments are provided below to verify the effects of the apparatuses of the disclosure. However, the scope of the disclosure is not limited to the following experiments.

Apparatus for electroplating: as shown in the apparatus for electroplating in FIG. 4, the first electrode is a copper electrode plate, and the copper electrode plate is connected to a positive electrode; the second electrode is a titanium electrode plate, and the titanium electrode plate is connected to a negative electrode.

Substrate: a p-type silicon wafer for which a 200 nm silver layer is coated on the surface, wherein the diameter of the silicon wafer is 3 in., the thickness thereof is 375 μm, and the silicon wafer resistivity is 0.05 ohm-cm.

Electroplating

First, the substrate was placed on a titanium electrode plate, the surface (coated with silver layer) to be electroplated was placed facing up, and the back of the substrate was in contact with the titanium electrode in the middle of the platform. Then, the electroplating solution spraying head was placed above the substrate at a distance of 10 mm from the substrate. A copper sulfate electroplating solution was continuously poured into the electroplating solution spraying head such that the substrate surface was uniformly covered with the electroplating solution. The solution film height was maintained at 5 mm, the electroplating solution was allowed to flow continuously, and the flow velocity was 2 liter/min. The current was turned on, and the current density was set to 0.01 Å/cm² for 30 seconds. It was observed that a copper layer was indeed plated on the silicon wafer surface.

Based on the above, the disclosure at least has the following effects:
1. In the disclosure, the large amount of bubbles generated by etching or electroplating etching is removed by a flowing solution, and therefore accumulation of bubbles can be prevented, such that current is not readily short-circuited and etching or electroplating is more uniform.
2. The (positive) electrode in the apparatus for etching of the disclosure is not in contact with the etching solution, and thus any conductive metal material can be used.
3. In the disclosure, the (negative electrode) current is turned on via a solution, and therefore only an electrode rod needs to be immersed in the etching solution, and the amount of white gold or silver used can be minimized under the premise of uniform current, so as to reduce costs of the apparatus.
4. The etching solution or the electroplating solution of the disclosure is sprayed continuously, thus solving the issue of difficult monitoring of solution height.
5. In the disclosure, a solution is used as a non-contact electrode by conductive properties thereof and electrochemical etching or electroplating reaction is performed as the solution flows, and therefore current uniformly passes through the substrate such that the solution can be more uniform when used in porous silicon etching or electroplating.
6. In the disclosure, current intensity can be adjusted via a single apparatus, and therefore a bilayer or even a multi-layer porous silicon layer can be etched without moving the wafer, such as forming a second porosity by directly changing current intensity after a first current intensity is applied to form a first porosity layer, and so on.
7. The apparatus of the disclosure can be mass produced, and can still retain etch uniformity after the process is enlarged, and the volume of the process apparatus can also be minimized, thus simplifying design and facilitating operation.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An apparatus for electrochemical etching a substrate including a first surface and a second surface, the apparatus comprising:
an etching solution spraying head;
a first electrode disposed inside the etching solution spraying head, wherein a current is provided to an etching solution inside the etching solution spraying head by the first electrode;
a support disposed opposite to the etching solution spraying head; and
a second electrode disposed on the support, wherein when the substrate is disposed on the second electrode, the first surface of the substrate is in electrical contact with the second electrode, and the etching solution sprayed from the etching solution spraying head naturally flows through the second surface of the substrate and then flows off from edges of the support.

2. The apparatus of claim 1, wherein an area of the substrate is greater than an area of the second electrode.

3. The apparatus of claim 1, wherein the first electrode is a negative electrode.

4. The apparatus of claim 1, wherein the first electrode is a platinum electrode or a silver electrode.

5. The apparatus of claim 1, wherein the etching solution is a mixed aqueous solution of hydrofluoric acid and alcohol.

6. The apparatus of claim 1, wherein a material of the etching solution spraying head and a material of the support independently comprise polytetrafluoroethylene (PTFE), polyvinyl difluoride (PVDF), a perfluoroalkoxy (PFA) resin, polyvinylchloride (PVC), polypropylene (PP), or high-density polyethylene (HDPE).

7. The apparatus of claim 1, wherein a spacing between the etching solution spraying head and the second electrode is controlled such that a liquid film formed by the etching solution on the second surface of the substrate is continuous.

8. The apparatus of claim 1, wherein the etching solution spraying head has a plurality of spray openings or a plurality of nozzles.

9. The apparatus of claim 1, wherein the support comprises at least one adsorption port for vacuum adsorbing the substrate by vacuum-pumping from the adsorption port.

10. The apparatus of claim 9, wherein the support further comprises at least one exhaust port disposed in a portion closer to the edges the support than a location of the adsorption port.

11. The apparatus of claim 9, further comprising an O-ring surrounding the second electrode and disposed between the substrate and the support to prevent the etching solution from being sucked by the adsorption port.

12. The apparatus of claim 1, further comprising a solution holding device for holding the etching solution flowing off from the edges of the support.

13. The apparatus of claim 1, further comprising a solution storage tank for storing the etching solution and transporting the etching solution from the solution storage tank to the etching solution spraying head via a pump pressure.

14. The apparatus of claim 1, wherein the substrate comprises a silicon wafer, a germanium wafer, a silicon germanium wafer, or a gallium arsenide wafer.

15. An apparatus for electroplating a substrate including a first surface and a second surface, the apparatus comprising:
an electroplating solution spraying head;
a first electrode disposed inside the electroplating solution spraying head, wherein a current is provided to an electroplating solution inside the electroplating solution spraying head by the first electrode;
a support disposed opposite to the electroplating solution spraying head; and
a second electrode disposed on the support,
wherein when the substrate is disposed on the second electrode, the first surface of the substrate is in electrical contact with the second electrode, and the electroplating solution sprayed from the electroplating solution spraying head naturally flows through the second surface of the substrate and then flows off from edges of the support.

16. The apparatus of claim 15, wherein the electroplating solution spraying head has a plurality of spray openings or a plurality of nozzles.

17. The apparatus of claim 15, wherein an area of the substrate is greater than an area of the second electrode.

18. The apparatus of claim 15, wherein the first electrode is a positive electrode.

19. The apparatus of claim 15, wherein the support comprises at least one adsorption port for vacuum adsorbing the substrate by vacuum-pumping from the adsorption port.

20. The apparatus of claim 19, wherein the support further comprises at least one exhaust port disposed in a portion closer to the edges of the support than a location of the adsorption port.

21. The apparatus of claim 19, further comprising an O-ring surrounding the second electrode and disposed between the substrate and the support to prevent the electroplating solution from being sucked by the adsorption port.

22. The apparatus of claim 15, wherein a spacing between the electroplating solution spraying head and the second electrode is controlled such that a liquid film formed by the electroplating solution on the second surface of the substrate is continuous.

23. The apparatus of claim 15, wherein a material of the first electrode is a metal material to be plated on the second surface of the substrate.

24. The apparatus of claim 15, further comprising a solution holding device for holding the electroplating solution flowing off from the edges of the support.

25. The apparatus of claim 15, further comprising a solution storage tank for storing the electroplating solution and transporting the electroplating solution from the solution storage tank to the electroplating solution spraying head via a pump pressure.
